(19) United States
(12) Patent Application Publication
(10) Pub. No.: US 2025/0226010 A1
(43) Pub. Date: Jul. 10, 2025

(54) ELECTRONIC DEVICE

(71) Applicant: STMicroelectronics International N.V., Geneva (CH)

(72) Inventors: Olivier WEBER, Grenoble (FR); Remy BERTHELON, Crolles (FR)

(73) Assignee: STMicroelectronics International N.V., Geneva (CH)

(21) Appl. No.: 19/003,996

(22) Filed: Dec. 27, 2024

(30) Foreign Application Priority Data
Jan. 2, 2024 (FR) FR2400013

(51) Int. Cl. G11C 5/06; H01L 23/522; H01L 23/528; H01L 23/532; H10B 63/00; H10B 63/10

(52) U.S. Cl. CPC G11C 5/063; H01L 23/5226; H01L 23/5283; H01L 23/53228; H01L 23/53257; H10B 63/10; H10B 63/30

(57) ABSTRACT

A memory circuit includes a semiconductor substrate having selection transistors arranged therein, the semiconductor substrate including first regions and second regions, the first regions forming first rows extending in a first direction, the second regions forming second rows extending in the first direction. The memory circuit includes an interconnection stack including a succession of levels including first and second insulating layers, having interconnection elements defined therein. The memory circuit includes a plurality of memory cells arranged above a level of the stack, each memory cell being coupled to a first region by at least one interconnection element, the second regions of a same second row being coupled together by interconnection elements located in the at least one level of the stack.

### CROSS-REFERENCE TO RELATED APPLICATION(S)

The present application is based on, and claims priority from, French patent application 2400013, filed on Jan. 2, 2024, entitled “Dispositif électronique”, which is incorporated by reference to the extent permitted by law.

### BACKGROUND

### Technical Field

The present disclosure generally concerns electronic devices and more particularly electronic devices including a memory circuit, in particular a phase-change memory circuit.

### Description of the Related Art

A phase-change material is a material having the ability to change crystalline state under the effect of heat, and more specifically to switch between a crystalline state and an amorphous state, more highly resistive than the crystalline state. This phenomenon is used to define two memory states, for example 0 and 1, differentiated by the resistance measured through the phase-change material.

There exists a need to improve electronic chips including a memory circuit including memory cells based on a phase-change material, and their manufacturing methods.

### BRIEF SUMMARY

An embodiment provides an electronic device including a memory circuit, the memory circuit including:
a semiconductor substrate having selection transistors arranged therein, the semiconductor substrate including first doped regions of a first conductivity type and second doped regions of a second conductivity type opposite to the first conductivity type, the first regions forming first rows extending in a first direction, the second regions forming second rows extending in the first direction;
an interconnection stack, arranged on the semiconductor substrate, including a succession of levels, each level including first and second insulating layers, having interconnection elements defined therein; and
a plurality of memory cells arranged above at least one level of the interconnection stack, each memory cell being coupled to a first region by at least one interconnection element, the second regions of a same second row being coupled together by interconnection elements located in said at least one level of the interconnection stack.

According to an embodiment, the semiconductor substrate includes, from an upper surface:
a third layer of the first conductivity type;
a fourth layer of the second conductivity type, the fourth layer being located on top of and in contact with the third layer; and
a fifth layer including the first and second regions, the fifth layer being located on top of and in contact with the fourth layer.

According to an embodiment, the fourth layer, the third layer, and the first and second regions of the fifth layer form the selection transistors.

According to an embodiment, the device includes first trenches extending in the first direction and second trenches extending in a second direction orthogonal to the first direction, the first and second trenches dividing the substrate into assemblies, each assembly including a first region and a second region.

According to an embodiment, the first and second regions of a assembly are separated by a third trench, the third trench having a height lower than the height of the first and second trenches.

According to an embodiment, the second trenches have a height lower than the height of the first trenches, the first and second regions of a assembly being separated by a third semiconductor region.

According to an embodiment, each memory cell is electrically coupled to a first region via a first conductive via running through the entire thickness of the at least one level of the interconnection stack.

According to an embodiment, the first conductive via is made of a metallic material.

According to an embodiment, the first conductive via is made of tungsten, of cobalt, or of copper.

According to an embodiment, the interconnection elements include second conductive vias and conductive tracks, the conductive tracks laterally extending over a surface area greater than the surface area of the second conductive via.

According to an embodiment, the device includes an alternation of first and second rows.

According to an embodiment, the two rows closest to each first or second row are a first and a second row.

According to an embodiment, each memory cell includes a sixth layer made of a phase-change material, a resistive element in contact with a lower surface of the sixth layer, and a seventh conductive layer in contact with an upper surface of the sixth layer.

According to an embodiment, a method includes forming a plurality of selection transistors including forming a plurality of first doped regions of a first conductivity type and a plurality of second doped regions of a second conductivity type opposite the first conductivity type. The first regions forming first rows extending in a first direction. The second regions forming second rows extending in the first direction. The method includes forming an interconnection stack arranged on the semiconductor substrate, including a succession of levels. Each level includes first and second insulating layers having interconnection elements therein. The method includes forming a plurality of memory cells arranged above at least one level of the interconnection stack. Each memory cell is coupled to a first region by at least one interconnection element. The second regions of a same second line being connected together by interconnection elements located in the at least one level of the interconnection stack.

According to an embodiment, a device includes a semiconductor substrate including a first layer of semiconductor material and a second layer of semiconductor material on the first layer of semiconductor material. The semiconductor substrate includes a plurality of first doped regions of a first conductivity type arranged in first rows in the second layer and a plurality of second of second doped regions of a second conductivity type arranged in second rows in the second layer. The device includes a plurality of first isolation trenches extending from a top of the semiconductor substrate through the second layer and partially into the second layer and each contacting at least one first doped region and at least one second doped region. The device includes a plurality of second isolation trenches extending from the top of the semiconductor substrate through an entirety of the first layer and each contacting at least one first doped region and at least one second doped region. The device includes a plurality of pairs of insulating layers stacked on each other, a plurality of memory cells above the pairs of insulating layers, and a plurality of conductive interconnection elements in the pairs of insulating layers.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the accompanying drawings, in which:

FIG. 1A, FIG. 1B, and FIG. 1C show an embodiment of an electronic device;

FIG. 2 shows another embodiment of an electronic device;

FIG. 3A and FIG. 3B show another embodiment of an electronic device; and

FIG. 4 shows a variant of the above-described embodiments.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

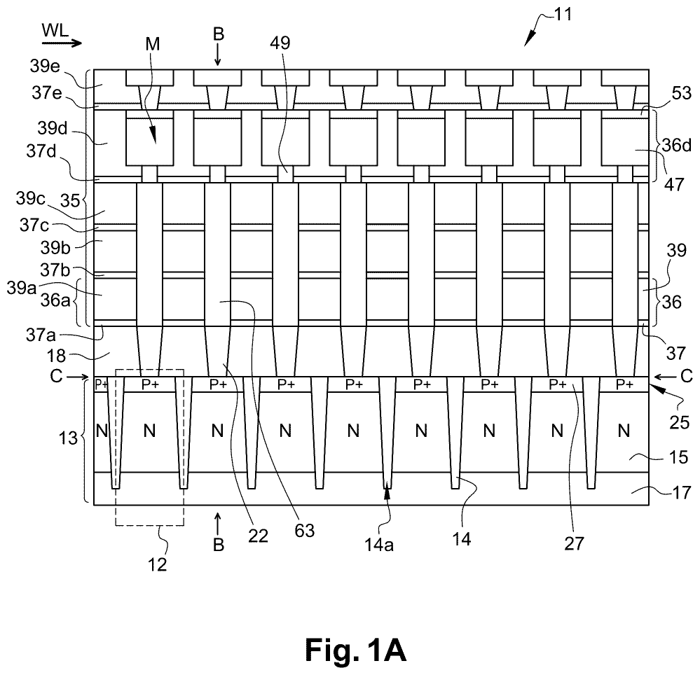

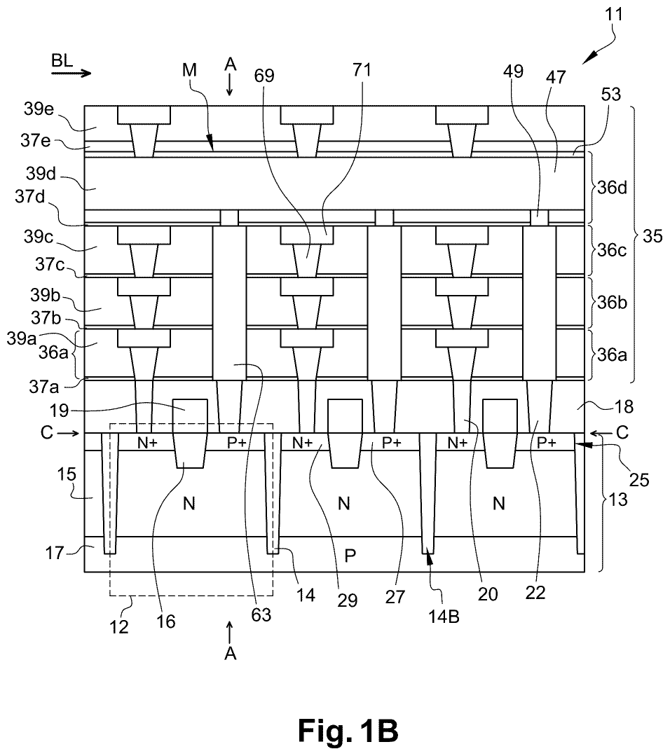

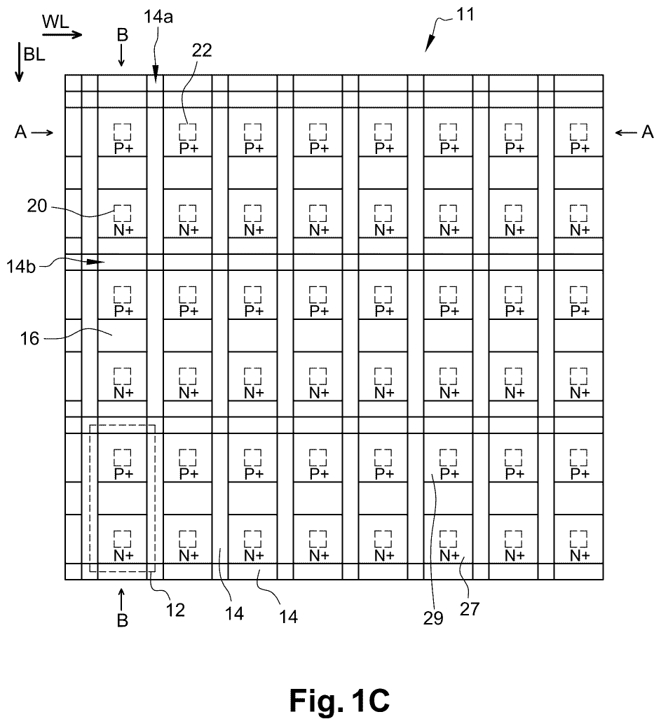

FIG. 1A, FIG. 1B, and FIG. 1C show an example of an electronic device 11, for example an electronic chip 11. More specifically, FIG. 1A is a cross-section view, partial and simplified, along a plane A-A of FIGS. 1B and 1C. FIG. 1B is a cross-section view, partial and simplified, along a plane B-B of FIGS. 1A and 1C. FIG. 1C is a cross-section view, partial and simplified, along a plane C-C of FIGS. 1A and 1B.

More particularly, FIGS. 1A to 1C illustrate a portion of a memory circuit of chip 11. As an example, chip 11 includes, in a portion not shown, a logic circuit adjacent to the memory circuit. The logic and memory circuits are, for example, simultaneously manufactured inside and on top of a same semiconductor substrate.

The electronic chip includes a semiconductor substrate 13. As an example, substrate 13 is made of silicon.

Substrate 13 includes, for example, a doped semiconductor layer 15 of a first conductivity type, for example of type N, for example doped with arsenic or phosphorus atoms. Layer 15 for example rests on, and is for example in contact with, another semiconductor layer 17 of substrate 13 doped with a second conductivity type, opposite to the first conductivity type, for example, type P, for example doped with boron atoms.

Substrate 13 includes, for example, a semiconductor layer 25. Layer 25 for example rests on layer 15. Thus, layer 25 is separated from layer 17 by layer 15. Layer 25 is for example flush with an upper surface of substrate 13.

Substrate 13 is divided into a plurality of assemblies 12. The assemblies 12 are preferably arranged in an array. The substrate thus includes rows and columns of assemblies 12. Each assembly 12 is associated with a memory cell M, and is preferably at least partially in front of said memory cell M.

Memory cells M are for example organized, in top view, in an array of rows and of columns. It is respectively spoken of word lines and of bit lines, each memory cell M being located at the intersection of a bit line and of a word line. As an example, the memory cells M illustrated in FIG. 1A are memory cells M of a same word line (WL), while the memory cells illustrated in FIG. 1B are memory cells of a same bit line (BL). In FIG. 1A, only eight bit lines are shown and in FIG. 1B only three word lines are shown. However, in practice, a memory circuit may include a different number of bit lines and of word lines, for example greater than eight and three. The array of assemblies 12 thus substantially corresponds to the array of memory cells M.

Assemblies 12 are separated from one another by insulating trenches 14. Insulating trenches 14 are, for example, shallow trench isolation (STI) trenches. Trenches 14 are, for example, divided into two categories: trenches 14a extending in a first direction, corresponding, for example, to the bit line direction, and trenches 14b extending in a second direction, corresponding, for example, to the word line direction. Insulating trenches 14a and 14b are, for example, orthogonal and form a grid.

Insulating trenches 14 extend, for example, from the upper surface of the substrate, preferably from the upper surface of layer 15. Trenches 14 preferably extend in layer 25, in layer 15, and in part of layer 17. As an example, each insulating trench 14b extends longitudinally in the word line direction, along the entire length of the word lines. As an example, each insulating trench 14a extends longitudinally in the bit line direction, along the entire length of the bit lines. Insulating trenches 14 are filled with a dielectric material, such as silicon oxide. The depth of trenches 14 is, for example, in the range from 250 nm to 400 nm.

Substrate 13 further includes insulating trenches 16, or insulation trenches 16. Trenches 16 are, for example, super shallow trench isolation (SSTI) trenches. As an example, each trench 16 extends longitudinally in the word line direction, along the entire length of the word lines. For example, trenches 16 extend vertically through layer 25 and through layer 15. More specifically, trenches 16 run through layer 25 and extend in part of layer 15. The height of trenches 16 is smaller than the height of layers 25 and 15. In other words, trenches 16 do not extend all the way to layer 17. Trenches 16 extend, for example, from the upper surface of layer 25. Insulating trenches 16 are for example filled with a dielectric material, for example silicon oxide. The depth of trenches 16 is, for example, in the range from 20 nm to 40 nm.

Each trench 16 is located between two trenches 14b. Thus, substrate 13 includes, in the bit line direction, an alternation of trenches 14b and of trenches 16. Each assembly 12 thus includes a portion of trench 16. Trenches 16 thus divide the portion of the layer 25 of each assembly 12 into two regions 27 and 29. Each assembly 12 thus includes a, preferably a single, region 27 and a, preferably a single, region 29. The regions 27 and 29 of a same assembly 12 are separated by trench 16.

Each region 27 or 29 preferably extends along the entire height of layer 25. Each region 27 or 29 is thus flush with the upper surface of layer 25. Each region 27 or 29 is for example in contact, by a lower surface, with layer 15.

Preferably, the regions 27 of assemblies 12 of a same row, or of a same column, are aligned. Similarly, the regions 29 of assemblies 12 of a same row, or of a same column, are aligned. Substrate 13 includes, in the embodiment of FIGS. 1A to 1C, rows of regions 27 extending in the word line direction and rows of regions 29 extending in the word line direction. Substrate 13 thus includes, in the example of FIGS. 1A to 1C, rows including an alternation of regions 27 and 29 extending in the bit line direction. Thus, in the bit line direction, substrate 13 includes an alternation of rows of regions 27 and of rows of regions 29.

Regions 27 are, for example, doped with the second conductivity type, for example, type P. Regions 27 are, for example, more heavily doped than layer 17. Each region 27 is, for example, topped with a memory cell M.

Regions 29 are, for example, doped with the first conductivity type, for example type N. Regions 29 are, for example, more heavily doped than layer 15. Regions 29, unlike regions 27, are not topped with memory cells M.

As an example, chip 11 includes dummy gate patterns 19 arranged on the upper surface of layer 25, for example extending longitudinally in the word line direction. Gate patterns 19 for example extend over trenches 16, for example, along the entire length of the trenches. Thus, a gate pattern 19 is, for example, common to all assemblies 12 forming a same row in the word line direction. Each gate pattern 19 is, for example, made of a semiconductor material, for example of silicon, for example of polysilicon.

Chip 11 includes an insulating layer 18 covering the upper surface of layer 25 and the upper surface of gate pattern 19. Insulating layer 18 is, for example, in contact with the upper surface of layer 25 and the upper surface of gate patterns 19. Insulating layer 18 for example covers the entire upper surface of layer 25. Insulating layer 18 for example has a thickness in the range from 80 nm to 300 nm, for example in the range from 120 nm to 200 nm.

Layer 18 includes conductive vias 20 and 22. Vias 20 and 22 are shown in dotted lines in FIG. 1C. Vias 20 and 22 are in contact with layer 25. More specifically, vias 20 are in contact, by a lower surface, with regions 29 and vias 22 are in contact, by a lower surface, with regions 27. Vias 20 and 22 extend, for example, along the entire height of layer 18. In other words, vias 20 and 22 extend from the upper surface of layer 18 to the lower surface of layer 18, that is, for example, from the upper surface of layer 18 to the upper surface of layer 25.

Layer 18 is topped with an interconnection stack 35. Interconnection stack 35 is for example formed on the upper surface of insulating layer 18 and for example covers the entire surface of insulating layer 18. Interconnection stack 35 is for example formed of a succession of levels 36, each level 36 including an insulating layer 37 and an insulating layer 39. Interconnection stack 35 for example includes a level 36a, including an insulating layer 39a formed on top of and in contact with the upper surface of insulating layer 18. Interconnection stack 35 further includes an insulating layer 37a formed on insulating layer 39a. For example, insulating layer 37a is formed over the entire surface of insulating layer 39a. As an example, insulating layer 37a is in contact, by its lower surface, with the upper surface of insulating layer 39a.

Interconnection stack 35 may further include additional levels formed on level 36a, that is, on top of and in contact with insulating layer 37a. In FIGS. 1A, 1B, and 1C, interconnection stack 35 includes four additional levels, for example respectively formed by layers 37b and 39b, layers 37c and 39c, layers 37d and 39d, and layers 37e and 39e. In practice, the number of levels in interconnection stack 35 may be different from five, for example greater than five.

As an example, interconnection stack 35 has a thickness in the range from 300 nm to 800 nm, for example in the range from 400 nm to 700 nm, for example in the order of 500 nm.

As an example, insulating layers 18 and 37 are made of a material having a low dielectric constant, for example a material having a dielectric constant (corresponding to the permittivity of said material relative to the permittivity of vacuum) smaller than 5, for example smaller than 4. Insulating layers 37 are for example made of silicon nitride or of SiCN. As an example, insulating layers 39 are made of an oxide having a low permittivity, known as “low k” or “ultra low k”.

Each level 36 includes vias 69 and tracks 71, tracks 71 extending in layer 39 from, for example, the upper surface of layer 39, thus flush with the upper surface of layer 39. Preferably, the tracks 71 of a level 36 extend exclusively in the layer 39 of said level 36. The vias 69 of a level of stack 35 extend through layer 39 and through layer 37. More specifically, the vias 69 of a level of stack 35 extend from the lower surface of a track 71 of the same level to the lower surface of layer 37. Preferably, each via 69 of a level of stack 35 is in contact by an upper surface with a lower surface of a track 71 of the same level 36 and is in contact, by a lower surface, with the upper surface of a track 71 of the lower level or with the upper surface of a via 20 or 22 running through layer 18.

The vias and conductive tracks 71 and 69 are made of a metallic material, for example of copper. As an example, conductive tracks 71 extend laterally over a surface area in the range from 20 nm by 20 nm to 60 nm by 60 nm, for example in the order of 30 nm by 30 nm. As an example, conductive tracks 71 extend laterally over a surface area greater than the surface area of vias 69.

Memory cells M are, in this embodiment, formed in a level 36d of stack 35. Level 36d includes layers 37d and 39d. More generally, the memory cells are located in any level of stack 35. Preferably, all the memory cells are located in the same level. For example, the memory cells are located in a level above the bottom level of the stack. In other words, the level of stack 35 containing memory cells M is preferably separated from layer 18 by at least one level of stack 35.

As an example, memory cells M are phase-change memory cells and each include a layer 47 made of a phase-change material, for example a chalcogenide material, for example, an alloy of germanium, antimony, and tellurium (GeSbTe) known as GST. Layer 47 has, for example, a thickness in the range from 30 nm and 100 nm, for example, in the order of 50 nm. Layer 47 is preferably located, preferably entirely, in layer 39d. The memory cells M of a same bit line, for example, include a common layer 47. Thus, chip 11 includes as many layers 47 as there are bit lines. Each layer 47 thus extends in layer 39d, in the bit line direction.

In each memory cell M, the phase-change material is, for example, controlled by a metallic resistive heating element 49 located under the phase-change material. Element 49 is for example in contact, by its upper level, with the lower surface of layer 47. The lower surface of each element 49 is for example coplanar with the lower surface of layer 37 of the level of stack 35 having memory cell M located therein, that is, layer 37d in the example of FIGS. 1A to 1C. As an example, heating element 49 has, for example, a thickness in the range from 30 nm to 100 nm, for example in the order of 60 nm.

Layer 47 is, for example, topped with a layer 53, for example made of a conductive material, for example of a metal. More specifically, the upper surface of each layer 47 is, for example, at least partially covered, for example entirely covered, by a layer 53. Each layer 53 preferably extends, in the bit line direction, along the entire length of layer 47. In the example of FIGS. 1A to 1C, each layer 53 is thus common to all the memory cells of the same bit line. Layer 53 is located in layer 36d, preferably in layer 39d, for example entirely in layer 39d. For example, the upper surface of layer 53 is flush with the upper surface of layer 39d.

As an example, in each memory cell M, metal element 49 and layer 53 respectively form a lower and an upper electrode of the memory cell, and more specifically of the variable-resistance resistive element formed by layer 47 of the phase-change material. As an example, the memory cells M of a same bit line are topped with the same layer 53. In other words, the upper electrodes 53 of the memory cells M of a same bit line are interconnected.

The memory cells M of neighboring bit lines are for example insulated from each other by insulating layer 39d and possibly layer 37d.

In the example of FIGS. 1A to 1C, for each memory cell M, assembly 12, including region 27 located vertically in line with memory cell M, the portion of layer 15 located in assembly 12, region 29, and the portion of layer 17 located in assembly 12, define a bipolar transistor, here of PNP type, for selecting memory cell M. Each memory cell M is for example associated with a bipolar transistor located in the assembly 12 located in front of the memory cell. In this example, region 27 forms an emitter region of the transistor, region 15 and region 29 form a base region of the transistor, and layer 17 forms a collector region of the transistor. As an example, the collector is common to all the transistors in the array and is, for example, connected to ground.

Each memory cell M is electrically connected to the selection transistor with which it is associated via a conductive via 63 running through all the levels of interconnection stack 35 located between the level including the memory cell and layer 18. As an example, via 63 runs through all the insulating layers 37 and 39 of interconnection stack 35 located between layer 37d and layer 18.

As an example, the via 63 associated with each memory cell M is in contact, by its upper surface, with the lower surface of the resistive heating element 49 of memory cell M. Via 63 is for example in contact, by its lower surface, with a conductive via 22, itself in contact with the upper surface of the region 27 of the assembly 12 associated with memory cell M. In other words, for each memory cell M, the corresponding via 63 electrically couples the heating element 49 of the memory cell to the underlying region 27.

Conductive via 63 is for example made of a metallic material. Conductive via 63 is for example made of tungsten. As a variant, the conductive via is made of cobalt or of copper. Conductive via 63 has, for example, a width, taken in the plane of FIG. 1A and in the plane of FIG. 1B, in the range from 20 nm to 80 nm, for example in the order of 40 nm.

The regions 29 of the layer 25 of the same word line are for example coupled together by conductive vias 69 and conductive tracks 71 located in levels of interconnection stack 35 located under the level in which the memory cells are located. Thus, the conductive vias 69 and the conductive tracks 71 coupling the regions 29 of the layer 25 of a same word line are located between the level including the memory cells and layer 18. In the example of FIGS. 1A to 1C, regions 29 are coupled to one another by vias 69 and tracks 71 located in levels 36a, 36b, and 36c, that is, in the three levels of stack 35 closest to layer 18.

Thus, in the bit line direction, chip 11, and more particularly the memory circuit, includes an alternation of first lines, each including a line of regions 29 and the tracks 71 and the vias 69 coupling said regions 29, and of second lines, each including a line of regions 27, the vias 63 in contact with said regions 27, and the memory cells associated with said regions 27. Thus, each via 63 associated with a memory cell M is separated from the vias 63 of neighboring word lines by the vias 69 and the tracks 71 coupling the regions 29 of a line of regions 29.

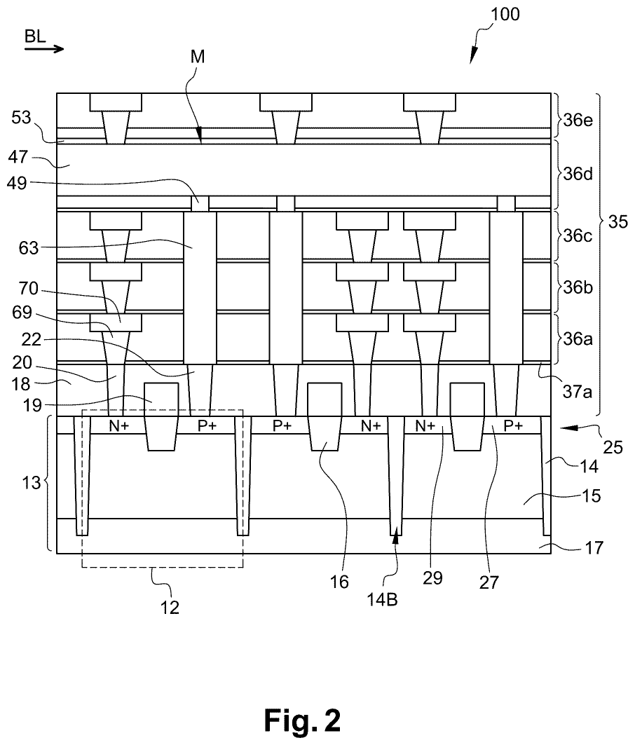

FIG. 2 shows another embodiment of an electronic device 100. More specifically, FIG. 2 shows a cross-section view, simplified and partial, of device 100 in a plane similar to the plane of FIG. 1B.

Device 100 includes the elements of device 11, which will not be described again in detail.

Device 100 differs from the device 11 of FIGS. 1A to 1C in that device 100 includes, in the bit line (BL) direction, an alternation of assemblies 12, regions 27 and 29 being inverted from one assembly to the other. In other words, in the bit line direction, each region 27 or 29 is located between a region 27 and a region 29. Thus, each region 27 or 29 includes, in the bit line direction, a neighboring region 27 and a neighboring region 29. Device 100 includes first rows of regions 27 and second rows of regions 29, the first and second rows extending in the word line direction. Each first and second row is located between a first row and a second row. Thus, the two rows closest to each first or second row are a first row and a second row. Thus, each trench 14b separates, preferably directly, two regions 27 or two regions 29. Each region 27 is separated from a region 29 by a trench 16 and from a region 27 by a trench 14b. Each region 29 is separated from a region 29 by a trench 14b and from a region 27 by a trench 16.

As in the previously described embodiments, each region 27 is topped with vias 22 and 63 and with a memory cell M. Each region 29 is topped with a via 20 and with an alternation of vias 69 and of tracks 71 coupling together the regions 29 of a same row of regions 29. Thus, each via 63 is located between a via 63 and an alternation of vias 69 and of track 71.

The structure of FIG. 2 includes neighboring regions 27 and neighboring regions 29. Neighboring regions 27 and neighboring regions 29 may advantageously be simultaneously doped, which enables to form wider mask openings. Furthermore, such a placement allows the decrease of the dimensions of the memory cells. Indeed, the regions 27 and 29 can now have dimensions lower than the minimal dimensions of the manufacturing method of semiconductor regions.

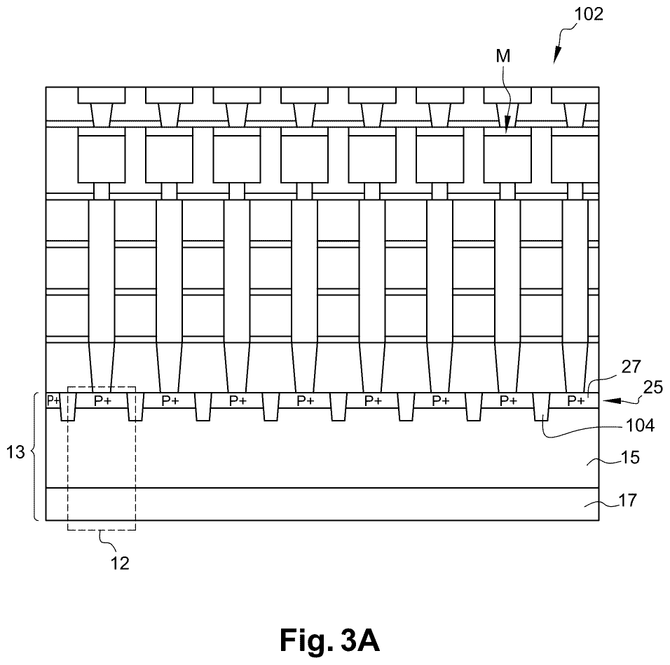

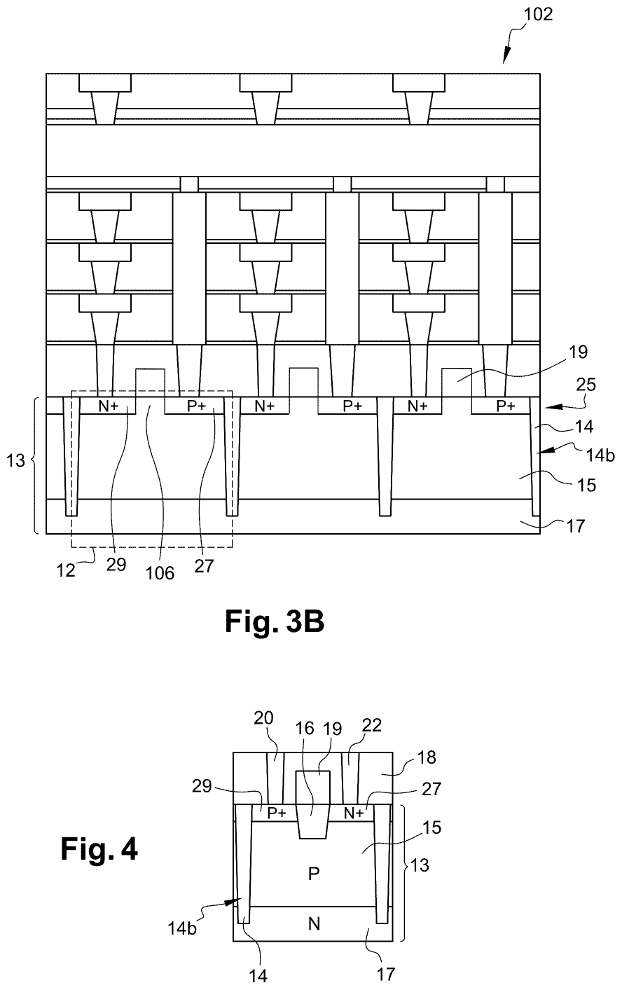

FIG. 3A and FIG. 3B show another embodiment of an electronic device 102. More specifically, FIG. 3A shows a cross-section view, simplified and partial, of device 102 along a plane A-A of FIG. 3B, and FIG. 3B corresponds to a cross-section view, simplified and partial, of device 102 along a plane B-B of FIG. 3A.

Device 102 includes the elements of device 11 which will not be described again in detail.

Device 102 differs from the device 11 of FIGS. 1A to 1C in that trenches 14a are replaced with insulating trenches 104. Trenches 104 are, for example, super shallow trench isolation (SSTI) trenches. As an example, trenches 104 extend vertically in layer 25 and in layer 15. More specifically, trenches 104 run through layer 25 and extend in part of layer 15. Preferably, the height of trenches 104 is smaller than the height of layers 25 and 15. In other words, trenches 104 preferably do not extend all the way to layer 17. Trenches 104 extend, for example, from the upper surface of layer 25. Insulating trenches 104 are, for example, filled with a dielectric material, for example silicon oxide. The depth of trenches 104 is, for example, in the range from 20 nm to 40 nm.

Further, device 102 differs from device 11 in that device 102 does not include the trenches 16 separating the regions 27 and 29 of a single assembly 12. The regions 27 and 29 of a same assembly 12 are thus separated by a region 106 of layer 25. Each region 106 is thus located, in layer 25, at the location of trench 16. Regions 106 are preferably made of the same semiconductor material as layer 15, for example silicon. Regions 106 are, for example, doped with the same conductivity type as layer 15. For example, regions 106 have the same dopant concentration as layer 15. Preferably, regions 106 have a dopant concentration lower than the dopant concentration of regions 29.

An advantage of the embodiment of FIG. 3 is that it avoids the implementation of a manufacturing method for double shallow trench insulation, with two depths, which implies a double etching of trenches, a double filling and a double planarization step. Such a method is long and costly.

FIG. 4 shows a variant of the embodiments described hereabove. More specifically, FIG. 4 shows a portion of the embodiment of FIG. 1B according to a variant.

In the variant of FIG. 4, the conductivity types of the layers and regions of substrate 13 are inverted. Thus, layer 17 is N-type doped, layer 15 is P-type doped, regions 27 are N-type doped, and regions 29 are P-type doped, more heavily than layer 15. Thus, the selection transistor of each memory cell is an NPN-type bipolar transistor.

An advantage of the embodiment of FIGS. 1A to 1C is that the distance between memory cells is substantially constant, which enables to avoid disturbances from one cell to the other.

An advantage of the embodiment of FIG. 2 is that neighboring regions 27 and neighboring regions 29 can be doped simultaneously, which enables to form larger mask openings.

An advantage of the embodiment of FIG. 4 is that an NPN bipolar transistor generally has a better Beta factor Ic/Ib than a PNP bipolar transistor. There thus possibly is a draining off of less current in the base and of more current in the collector for a same emitter current. There thus is less voltage on the word lines.

An advantage of the present embodiments including vias 63 is that the lack of conductive tracks in the layers 37 diminish the risks of parasitic capacitances, facilitating forming layers 37 in a materials other than those having a low dielectric constant.

An advantage of the present embodiments is that it enables to do away with metal level sizing constraints for PCM cell integration, since the surface area of vias 63 can be smaller than the surface area of a track 71 at the surface of interconnection stack 35. This embodiment advantageously includes no vias 69 and tracks 71.

Another advantage of the present embodiments including vias 63 is that the forming of the memory cells above interconnection level 36 enables to do away with risks of contamination of the PCM layer of the memory cell generated by the forming of the interconnection stack and of the various metal levels 71 and 69.

Still another advantage of the present embodiments is that it is compatible with known methods and logic parts, the logic part not being impacted.

Various embodiments and variants have been described. Those skilled in the art will understand that certain features of these various embodiments and variants may be combined, and other variants will occur to those skilled in the art. In particular, although each region 27 is coupled to the memory cell by a via 22 and a single via 63 running through the levels of stack 35 separating the memory cell and layer 18, via 63 can be replaced, in all the described embodiments, with a succession of tracks 71 and of vias 69 located in the levels of stack 35 separating the memory cell and layer 18.

Finally, the practical implementation of the described embodiments and variants is within the abilities of those skilled in the art based on the functional indications given hereabove.

In one embodiment, an electronic device (11, 100, 102) including a memory circuit, the memory circuit including: a semiconductor substrate (13) having selection transistors arranged therein, the semiconductor substrate (13) including first doped regions (27) of a first conductivity type (P, N) and second doped regions (29) of a second conductivity type (N, P) opposite to the first conductivity type, the first regions forming first rows extending in a first direction (WL), the second regions forming second rows extending in the first direction (WL); an interconnection stack (35), arranged on the semiconductor substrate (13), including a succession of levels, each level including first (37) and second (39) insulating layers, having interconnection elements (63, 71, 69) defined therein; a plurality of memory cells (M) arranged above at least one level of the interconnection stack (35), each memory cell being coupled to a first region (27) by at least one interconnection element (63, 69, 71), the second regions (29) of a same second line being connected together by interconnection elements (69, 71) located in said at least one level of the interconnection stack (35).

In one embodiment, the semiconductor substrate (13) includes, from an upper surface: a third layer (17) of the first conductivity type; a fourth layer (15) of the second conductivity type, the fourth layer being located on top of and in contact with the third layer (17); and a fifth layer (25) including the first (27) and second (29) regions, the fifth layer being located on top of and in contact with the fourth layer (15).

In one embodiment, the fourth layer (15), the third layer (17), and the first (27) and second (29) regions of the fifth layer (25) may form the selection transistors.

In one embodiment, the device includes first trenches (14, 14b) extending in the first direction (WL) and second trenches (14, 14a, 104) extending in a second direction (BL) orthogonal to the first direction, the first and second trenches dividing the substrate into assemblies (12), each assembly (12) including a first region (27) and a second region (29).

In one embodiment, the first (27) and second (29) regions of an assembly (12) are separated by a third trench (16), the third trench (16) having a height smaller than the height of the first (14, 14b) and second (14, 14a) trenches.

In one embodiment, the second trenches (104) have a height smaller than the height of the first trenches (14, 14b), the first (27) and second (29) regions of an assembly (12) being separated by a third semiconductor region (106).

In one embodiment, each memory cell (M) is electrically coupled to a first region (27) via a first conductive via (63) running through the entire thickness of at least one level of the interconnection stack (35).

In one embodiment, the first conductive via (63) is made of a metallic material.

In one embodiment, the first conductive via (63) is made of tungsten, of cobalt, or of copper.

In one embodiment, the interconnection elements includes second conductive vias (69) and conductive tracks (71), the conductive tracks (71) laterally extending over a surface area greater than the surface area of the second conductive via (63).

In one embodiment, the device includes an alternation of first and second rows.

In one embodiment, the two rows closest to each first or second row are a first and a second row.

In one embodiment, each memory cell (M) includes a sixth layer (47) made of a phase-change material, a resistive element (49) in contact with a lower surface of the sixth layer, and a seventh conductive layer (53) in contact with an upper surface of the sixth layer.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic device comprising a memory circuit, the memory circuit including:
a semiconductor substrate having selection transistors arranged therein, the semiconductor substrate including first doped regions of a first conductivity type and second doped regions of a second conductivity type opposite the first conductivity type, the first regions forming first rows extending in a first direction, the second regions forming second rows extending in the first direction;
an interconnection stack arranged on the semiconductor substrate, including a succession of levels, each level including first and second insulating layers having interconnection elements therein; and
a plurality of memory cells arranged above at least one level of the interconnection stack, each memory cell being coupled to a first region by at least one interconnection element, the second regions of a same second line being connected together by interconnection elements located in the at least one level of the interconnection stack.

2. The device according to claim 1, wherein the semiconductor substrate includes, from an upper surface:
a third layer of the first conductivity type;
a fourth layer of the second conductivity type on top of and in contact with the third layer; and
a fifth layer including the first and second regions, the fifth layer being located on top of and in contact with the fourth layer.

3. The device according to claim 2, wherein the fourth layer, the third layer, and the first and second regions of the fifth layer form the selection transistors.

4. The device according to claim 1, comprising first trenches extending in the first direction and second trenches extending in a second direction orthogonal to the first direction, the first and second trenches dividing the substrate into assemblies, each assembly including a first region and a second region.

5. The device according to claim 4, wherein the first and second regions of an assembly are separated by a third trench, the third trench having a height smaller than a height of the first and second trenches.

6. The device according to claim 4, wherein the second trenches have a height smaller than a height of the first trenches, the first and second regions of an assembly being separated by a third semiconductor region.

7. The device according to claim 1, wherein each memory cell is electrically coupled to a first region via a first conductive via running through an entire thickness of at least one level of the interconnection stack.

8. The device according to claim 7, wherein the first conductive via is made of a metallic material.

9. The device according to claim 7, wherein the first conductive via is made of tungsten, of cobalt, or of copper.

10. The device according to claim 1, wherein the interconnection elements include second conductive vias and conductive tracks, the conductive tracks laterally extending over a surface area greater than a surface area of the second conductive via.

11. The device according to claim 1, comprising an alternation of first and second rows.

12. The device according to claim 1, wherein the two rows closest to each first or second row are a first and a second row.

13. The device according to claim 1, wherein each memory cell includes a sixth layer of a phase-change material, a resistive element in contact with a lower surface of the sixth layer, and a seventh conductive layer in contact with an upper surface of the sixth layer.

14. A method, comprising: forming a plurality of selection transistors including forming a plurality of first doped regions of a first conductivity type and a plurality of second doped regions of a second conductivity type opposite the first conductivity type, the first regions forming first rows extending in a first direction, the second regions forming second rows extending in the first direction;
forming an interconnection stack arranged on the semiconductor substrate, including a succession of levels, each level including first and second insulating layers having interconnection elements therein; and
forming a plurality of memory cells arranged above at least one level of the interconnection stack, each memory cell being coupled to a first region by at least one interconnection element, the second regions of a same second line being connected together by interconnection elements located in the at least one level of the interconnection stack.

15. The method of claim 14, wherein the semiconductor substrate includes, from an upper surface:
a third layer of the first conductivity type;
a fourth layer of the second conductivity type on top of and in contact with the third layer; and
a fifth layer including the first and second regions, the fifth layer being located on top of and in contact with the fourth layer.

16. The method of claim 15, wherein the fourth layer, the third layer, and the first and second regions of the fifth layer form the selection transistors.

17. The method of claim 14, wherein each memory cell is electrically coupled to a first region via a first conductive via running through an entire thickness of at least one level of the interconnection stack.

18. A device, comprising:
a semiconductor substrate including:
a first layer of semiconductor material;
a second layer of semiconductor material on the first layer of semiconductor material;
a plurality of first doped regions of a first conductivity type arranged in first rows in the second layer; and
a plurality of second of second doped regions of a second conductivity type arranged in second rows in the second layer;
a plurality of first isolation trenches extending from a top of the semiconductor substrate through the second layer and partially into the second layer and each contacting at least one first doped region and at least one second doped region;
a plurality of second isolation trenches extending from the top of the semiconductor substrate through an entirety of the first layer and each contacting at least one first doped region and at least one second doped region;
a plurality of pairs of insulating layers stacked on each other;
a plurality of memory cells above the pairs of insulating layers; and
a plurality of conductive interconnection elements in the pairs of insulating layers.

19. The device of claim 18, wherein the conductive interconnection elements electrically coupling each memory cell to a first region.

20. The device of claim 19, wherein the conductive interconnection elements electrically couple each of the second doped regions of a same line.
